(19) United States
(12) Patent Application Publication
(10) Pub. No.: US 2024/0015964 A1
(43) Pub. Date: Jan. 11, 2024

(54) SEMICONDUCTOR DEVICE AND MANUFACTURING METHOD OF THE SEMICONDUCTOR DEVICE

(71) Applicant: SK hynix Inc., Icheon-si Gyeonggi-do (KR)

(72) Inventors: Young Tae YOO, Icheon-si Gyeonggi-do (KR); Jin Ho BIN, Icheon-si Gyeonggi-do (KR); Ah Reum BAHK, Icheon-si Gyeonggi-do (KR)

(73) Assignee: SK hynix Inc., Icheon-si Gyeonggi-do (KR)

(21) Appl. No.: 17/967,116

(22) Filed: Oct. 17, 2022

(30) Foreign Application Priority Data
Jul. 6, 2022 (KR) 10-2022-0082840

(51) Int. Cl. H01L 27/11582; H01L 27/11556; H01L 23/528

(52) U.S. Cl. CPC H01L 27/11582; H01L 27/11556; H01L 23/5283

(57) ABSTRACT

A semiconductor device including a first source layer including a first part having a first grain size and a second part having a second grain size smaller than the first grain size, a gate structure on the first source layer, and a channel structure passing through the gate structure and the second part of the first source layer.

### CROSS-REFERENCE TO RELATED APPLICATION

This application claims priority under 35 U.S.C. § 119(a) to Korean Patent Application No. 10-2022-0082840 filed on Jul. 6, 2022, which is incorporated herein by reference in its entirety.

### BACKGROUND

### 1. Technical Field

Embodiments of the present disclosure relate to an electronic device, and more particularly, to a semiconductor device and a manufacturing method of the semiconductor device.

### 2. Related Art

The degree of integration of a semiconductor device is mainly determined by an area occupied by a unit memory cell. Recently, as the improvement in the degree of integration of a semiconductor device for forming memory cells in a single layer on a substrate reaches a limit, a three-dimensional semiconductor device for stacking memory cells on a substrate has been proposed. Furthermore, in order to improve the operational reliability of such a semiconductor device, various structures and manufacturing methods have been developed.

### SUMMARY

In an embodiment, a semiconductor device may include: a first source layer including a first part having a first grain size and a second part having a second grain size smaller than the first grain size; a gate structure on the first source layer; and a channel structure extending to the first part of the first source layer through the gate structure and the second part of the first source layer.

In an embodiment, a semiconductor device may include: a first source layer including a first part and a second part, wherein the second part has a denser grain structure than the first part; a gate structure on the first source layer; a second source layer located between the first source layer and the gate structure; and a source contact structure extending to the first source layer through the gate structure and the second source layer, wherein the second part extends along an interface between the first source layer and the second source layer.

In an embodiment, a manufacturing method of a semiconductor device may include: forming a first part of a first source layer, the first part having a first grain size; forming a second part of the first source layer on the first part, the second part having a second grain size smaller than the first grain size; forming a stack on the first source layer; and forming a channel structure passing through the stack and the second part.

In an embodiment, a manufacturing method of a semiconductor device may include: forming a first part of a source layer; forming a second part of the source layer on the first part, the second part having a denser grain structure than the first part; forming a stack including first material layers and second material layers that are alternately stacked, on the source layer; forming an opening passing through the stack and exposing the second part; and forming a passivation layer by partially oxidizing the second part through the opening.

### BRIEF DESCRIPTION OF THE DRAWINGS

FIG. 1A and FIG. 1B are diagrams illustrating the structure of a semiconductor device in accordance with an embodiment.

FIG. 2 is a diagram diagrams the structure of a semiconductor device in accordance with an embodiment.

FIG. 3A and FIG. 3B are diagrams for describing a manufacturing method of a semiconductor device in accordance with an embodiment.

FIGS. 4A, 4B, 4C, 4D, 4E, 4F, and 4G are diagrams for describing a manufacturing method of a semiconductor device in accordance with an embodiment.

### DETAILED DESCRIPTION

Various embodiments are directed to a semiconductor device having a stable structure and improved characteristics and a manufacturing method thereof.

By stacking memory cells in three dimensions, it is possible to improve the degree of integration of a semiconductor device. Furthermore, it is possible to provide a semiconductor device having a stable structure and improved reliability.

Hereafter, embodiments in accordance with the technical spirit of the present disclosure will be described with reference to the accompanying drawings.

It will be understood that when an element or layer etc., is referred to as being “on,” “connected to” or “coupled to” another element or layer etc., it can be directly on, connected or coupled to the other element or layer etc., or intervening elements or layers etc., may be present. In contrast, when an element or layer etc., is referred to as being “directly on,” “directly connected to” or “directly coupled to” another element or layer etc., there are no intervening elements or layers etc., present. It will be understood that although the terms first, second, third etc. may be used herein to describe various elements, these elements should not be limited by these terms. These terms are only used to distinguish one element from another element, but not used to define only the element itself or to mean or infer a particular sequence.

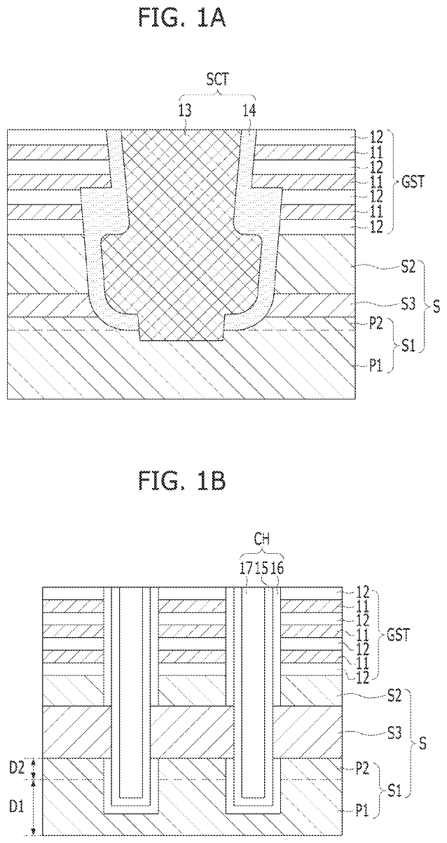

FIG. 1A and FIG. 1B are diagrams illustrating the structure of a semiconductor device in accordance with an embodiment.

Referring to FIG. 1A and FIG. 1B, the semiconductor device may include a source structure S and a gate structure GST. The semiconductor device may further include a channel structure CH or a source contact structure SCT, or may further include a combination thereof.

The source structure S may have a single-layer or multi-layer structure. In an embodiment, the source structure S may include a first source layer S1, a second source layer S2, or a third source layer S3, or a combination thereof. The source structure S may include a conductive material such as polysilicon, tungsten, or metal.

The first source layer S1 may include a first part P1 and a second part P2. The first part P1 and the second part P2 may have different depths from the surface of the first source layer S1. The second part P2 may be located at a second depth D2 from the surface of the first source layer S1. The first part P1 is a surface of the first source layer S1 and may be located at a first depth D1 deeper than the second depth D2. The second part P2 may be located closer to the surface of the first source layer S1 than the first part P1. The second part P2 may include the surface of the first source layer S1

The first part P1 and the second part P2 may have a polycrystalline structure and may have different grain structures. The first part P1 may have a first grain size, and the second part P2 may have a second grain size different from the first grain size. The second grain size may be smaller than the first grain size. The grain size may be an average grain size, a minimum grain size, or a maximum grain size of a corresponding part or a corresponding layer.

The first part P1 and the second part P2 may have different grain boundary densities. The first part P1 may have a first grain boundary density, and the second part P2 may have a second grain boundary density different from the first grain boundary density. The second grain boundary density may be greater than the first grain boundary density.

In an embodiment, the second part P2 may have a denser grain structure than the first part P1. The second part P2 may have a smaller grain size than the first part P1. The second part P2 may have a higher grain boundary density than the first part P1.

The second source layer S2 may be located between the first source layer S1 and the gate structure GST. The second part P2 of the first source layer S1 may be located between the first part P1 and the second source layer S2. The second part P2 may have a smaller grain size than the second source layer S2.

The third source layer S3 may be located between the first source layer S1 and the second source layer S2. The second part P2 of the first source layer S1 may be located between the first part P1 and the third source layer S3. The second part P2 may have a smaller grain size than the third source layer S3. The second part P2 may extend along an interface between the first source layer S1 and the third source layer S3. In an embodiment, the second part P2 may extend between the first source layer S1 and the third source layer S3 and be in direct contact with the first source layer S1 and the third source layer S3.

The gate structure GST may include conductive layers 11 and insulating layers 12 that are alternately stacked. The conductive layers 11 may be access lines such as word lines, bit lines, and selection lines. The conductive layers 11 may each include a conductive material such as polysilicon, tungsten, molybdenum, or metal. The insulating layers 12 may each include an insulating material such as an oxide, a nitride, or an air gap.

Referring to FIG. 1A, the source contact structure SCT may extend to the source structure S through the gate structure GST. The source contact structure SCT may pass through the second source layer S2 and the third source layer S3, and may extend into the first source layer S1. The source contact structure SCT may include a contact plug 13 and an insulating spacer 14. The contact plug 13 may be electrically connected to the first source layer S1. The contact plug 13 may come into contact with the first part P1 of the first source layer S1. In an embodiment, the source contact structure SCT may be directly connected to the first source layer S1. In an embodiment, the contact plug 13 may come into direct contact with or be directly coupled to the first part P1 of the first source layer S1.

The insulating spacer 14 may surround a sidewall of the contact plug 13. The insulating spacer 14 may be located between the contact plug 13 and the gate structure GST. The insulating spacer 14 may be located between the contact plug 13 and the second source layer S2 and between the contact plug 13 and the third source layer S3. The insulating spacer 14 may be located between the contact plug 13 and the second part P2. The contact plug 13 may be spaced apart from the second part P2. In an embodiment, the contact plug 13 may be separated from the second part P2 by the insulating spacer 14.

Referring to FIG. 1B, the channel structure CH may extend to the source structure S through the gate structure GST. The channel structure CH may pass through the second source layer S2 and the third source layer S3, and may extend into the first source layer S1. The channel structure CH may pass through the second part P2 of the first source layer S1. A memory cell, a selection transistor, and the like may be located in a region where the channel structure CH and the conductive layers 11 cross each other.

The channel structure CH may include a channel layer 15. The channel structure CH may further include a memory layer 16 or an insulating core 17, or may further include a combination thereof. The channel layer 15 may include a semiconductor material such as silicon or germanium. The memory layer 16 may include a blocking layer, a data storage layer, or a tunneling layer, or a combination thereof. The data storage layer may include a floating gate, a polysilicon layer, a charge trap material, a nitride layer, a variable resistance material, and the like. The insulating core 17 may include an insulating material such as an oxide, a nitride, or an air gap.

For reference, the semiconductor device may also include an electrode structure instead of the channel structure CH. The electrode structure may include an electrode layer passing through the gate structure GST, and may further include a memory layer surrounding an outer wall or inner wall of the electrode layer. The memory layer may include a variable resistance material.

Although the structure in which the channel structure CH comes into direct contact with the third source layer S3 has been described in the present embodiment, the present disclosure is not limited thereto. For example, the channel structure CH may also be connected to the third source layer S3 through an epitaxial pattern or the like.

According to the structure as described above, the first source layer S1 may have a different grain structure depending on the region. The second part P2 may have a denser grain structure than the first part P1. As the second part P2 may be used as a chemical diffusion barrier due to its denser grain structure, the first source layer S1 may have a rigid structure.

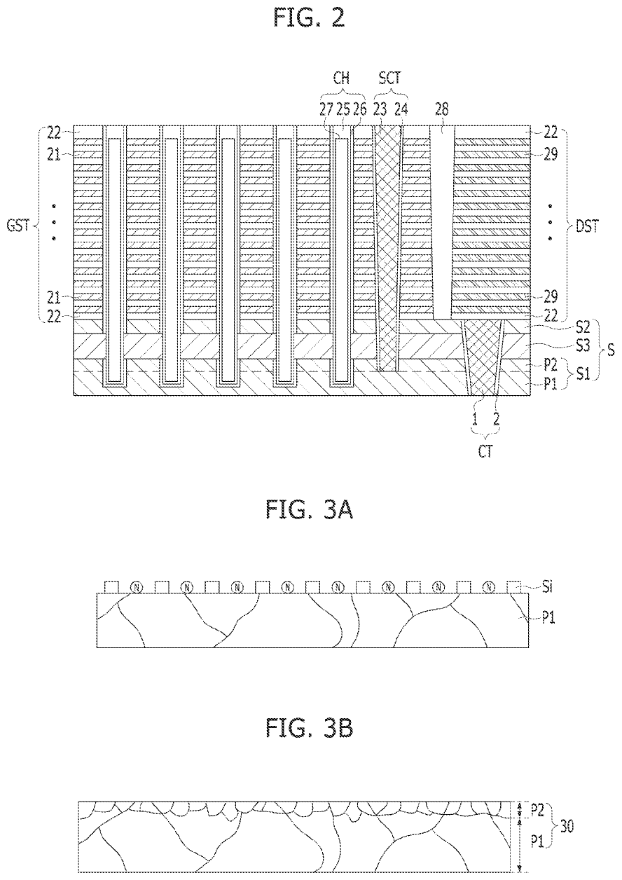

FIG. 2 is a diagram illustrating a structure of a semiconductor device according to an embodiment of the present disclosure. Hereinafter, the content overlapping the previously described content will be omitted.

Referring to FIG. 2, the semiconductor device may include a source structure S, a gate structure GST, a dummy stack DST, a channel structure CH, a source contact structure SCT, a slit structure 28, or a contact structure CT, or a combination thereof.

The source structure S may include a first source layer S1, a second source layer S2, or a third source layer S3, or a combination thereof. The first source layer S1 may include a first part P1 and a second part P2 having a smaller grain size than the first part P1. The second part P2 may have a smaller grain size than the second source layer S2 or the third source layer S3.

The gate structure GST may include conductive layers 21 and insulating layers 22 that are alternately stacked. The conductive layers 21 may be access lines such as word lines, bit lines, and selection lines.

The dummy stack DST may include sacrificial layers 29 and the insulating layers 22 that are alternately stacked. The sacrificial layers 29 may remain without being replaced with the conductive layers 21 during a manufacturing process. The sacrificial layers 29 may each include a material having a high etch selectivity with respect to the insulating layers 22. In an embodiment, the sacrificial layers 29 may each include a nitride and the insulating layers 22 may each include an oxide.

The slit structure 28 may be located between the gate structure GST and the dummy stack DST. The slit structure 28 may be used as a support in the process of replacing the sacrificial layers 29 with the conductive layers 21. In an embodiment, the sacrificial layers 29 may be substituted for the conductive layers 21 on one side of the slit structure 28, and the sacrificial layers 29 on the other side of the slit structure 28 may remain without being replaced.

The source contact structure SCT may include a contact plug 23 and an insulating spacer 24. The channel structure CH may include a channel layer 25, a memory layer 26, or an insulating core 27, or a combination thereof. The semiconductor device may also include an electrode structure instead of the channel structure CH.

The contact structure CT may pass through the source structure S. The contact structure CT may pass through the second part P2 of the first source layer S1. The contact structure CT may include a contact plug 1, and may further include an insulating spacer 2 surrounding a sidewall of the contact plug 1. The contact structure CT may be used as a discharge contact for discharging an electric charge during the manufacturing process. Alternatively, the contact structure CT may further include a contact plug passing through the dummy stack DST, and may be used as a part of an interconnection connecting a peripheral circuit and a cell array.

The second part P2 of the first source layer S1 may be located below the gate structure GST and below the dummy stack DST. The channel structure CH, the source contact structure SCT, or the contact structure CT may pass through the second part P2.

According to the structure described above, the first source layer S1 may include the second part P2 having a smaller grain size than the first part P1. As the second part P2 may be used as a chemical diffusion barrier due to its smaller grain structure, the first source layer S1 may have a rigid structure.

For reference, the positions of the source structure S and the gate structure GST are relative and may be reversed. In an embodiment, the source structure S may be located above the gate structure GST. Although not illustrated in this drawing, a lower structure such as a peripheral circuit may be located below the source structure S. Alternatively, an upper structure such as a peripheral circuit may be located above the gate structure GST or the dummy stack DST. The upper structure or the lower structure may be formed in substantially the same chip as the source structure S and the gate structure GST. Alternatively, a cell chip including the source structure S and the gate structure GST and a peripheral circuit chip including the upper structure or the lower structure may be separately formed and then bonded.

FIG. 3A and FIG. 3B are diagrams for describing a manufacturing method of a semiconductor device in accordance with an embodiment. Hereinafter, the content overlapping the previously described content will be omitted.

Referring to FIG. 3A, a first part P1 of a conductive layer 30 may be formed. In an embodiment, the first part PI may have a first grain structure. Referring to FIG. 3B, a second part P2 of the conductive layer 30 may be formed. The second part P2 may be formed on the first part P1. The second part P2 may have a second grain structure different from the first grain structure. The conductive layer 30 may include a conductive material such as polysilicon or metal.

For example, the first part P1 and the second part P2 may be formed ex-situ. The first part P1 and the second part P2 may be formed using different chambers, respectively. In such a case, an interface may exist between the first part P1 and the second part P2. In another example, the first part P1 and the second part P2 may be formed in-situ. In substantially the same chamber, the second part P2 may be formed after the first part P1 is formed. Accordingly, the first part P1 and the second part P2 having different grain structures may be formed without an interface. As the interface is not formed in the conductive layer 30, the conductive layer 30 having a rigid structure may be formed.

The deposition conditions of the first part P1 and the deposition conditions of the second part P2 may be different so that the first part P1 and the second part P2 have different grain structures. First, referring to FIG. 3A, the first part P1 may be formed by supplying a silicon source gas such as SiH₄ into the chamber. In an embodiment, a first polysilicon layer having a first grain size or a first grain boundary density may be formed. Subsequently, silicon (Si) may be allowed to be absorbed onto the surface of the first part P1 to form silicon seeds.

Subsequently, an inhibit gas may be supplied to the surface of the first part P1 onto which the silicon is adsorbed. The inhibit gas is for suppressing or minimizing the migration or recombination of the silicon (Si) adsorbed onto the surface of the first part P1. The inhibit gas may include at least one of a nitrogen gas and a carbon gas. In an embodiment, the inhibit gas may include a nitrogen gas such as NH₃, N₂O, N₂, and suppress or minimize the migration or recombination of the silicon by nitrogen (N) or oxygen (O) included in the nitrogen gas.

Subsequently, referring to FIG. 3B, the second part P2 may be formed by growing or crystallizing the silicon from a plurality of silicon seeds. Accordingly, the second part P2 having a grain structure different from that of the first part P1 may be formed. In an embodiment, a second polysilicon layer having a second grain size different from the first grain size or a second grain boundary density different from the first grain boundary density may be formed. The second part P2 may have a nano-grain size in which the diameter of a grain is several nanometers (nm).

Accordingly, the conductive layer 30 having a different grain structure may be formed depending on the region. The grain structure of the conductive layer 30 may affect material diffusion. When chemicals used in the manufacturing process are introduced into the conductive layer 30, the degree of diffusion of the chemicals in the first part P1 and the degree of diffusion of the chemicals in the second part P2 may be different. The degree of diffusion of the chemicals in the second part P2 having a smaller grain size than the first part P1 may be small. The degree of diffusion of the chemicals in the second part P2 having a higher grain boundary density than the first part P1 may be small. Accordingly, the depth, grain structure, and the like of the first part P1 or the second part P2 may be designed in consideration of diffusion of the chemicals. In an embodiment, by reducing the grain size of the second part P2, the second part P2 may be used as a chemical diffusion barrier.

For reference, the conductive layer may be used for various purposes in the semiconductor device. The conductive layer may be applied not only to a source layer but also to various layers having conductivity such as contact plugs and interconnections. Furthermore, the conductive layer is applicable to various integrated circuits. The conductive layer is applicable not only to memory devices such as a volatile memory and a non-volatile memory, but also to processors, such as a central processing unit (CPU), a graphic processing unit (GPU), and an application processor (AP), controllers, and the like.

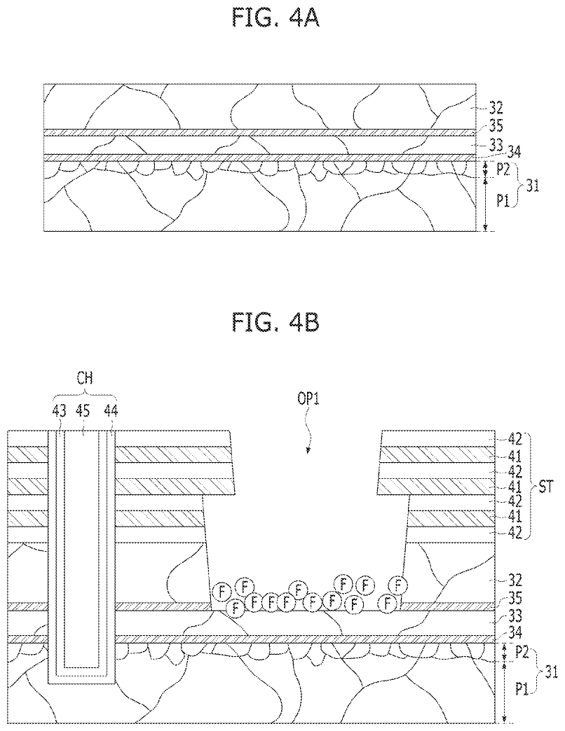

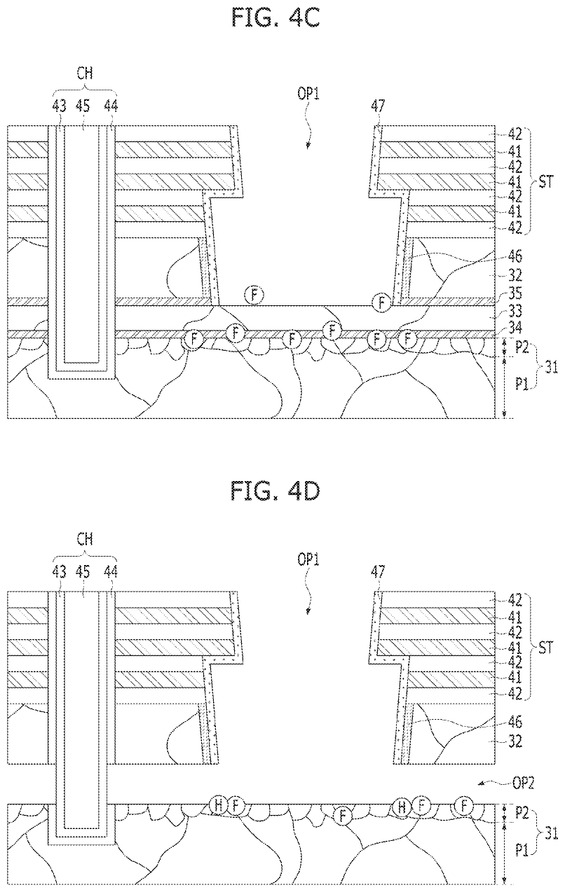

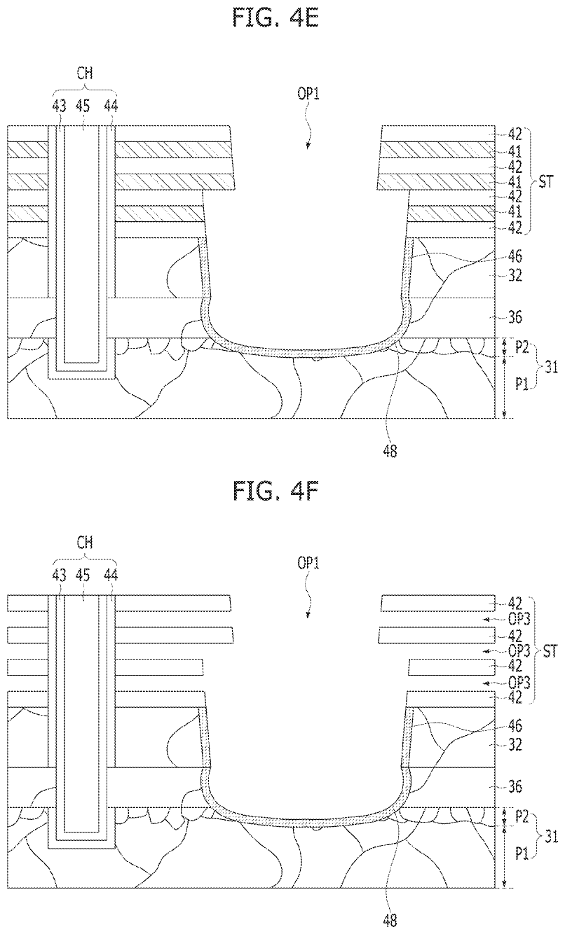

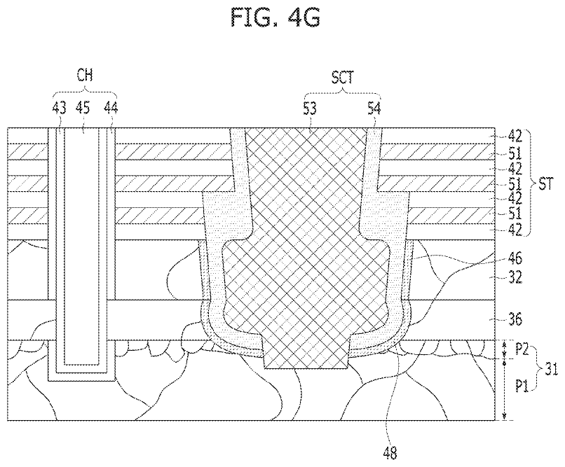

FIG. 4A to FIG. 4G are diagrams for describing a manufacturing method of a semiconductor device in accordance with an embodiment. Hereinafter, the content overlapping the previously described content will be omitted.

Referring to FIG. 4A, a first source layer 31 including a first part P1 and a second part P2 may be formed. The first source layer 31 may include a polysilicon layer. After the first part P1 is formed, the second part P2 may be formed using an inhibit gas. Accordingly, the first source layer 31 including the first part P1 and the second part P2 having different grain structures may be formed. The first part P1 may have a first grain size, and the second part P2 may have a second grain size smaller than the first grain size. The first part P1 and the second part P2 may be formed in-situ.

Subsequently, a sacrificial layer 33 may be formed on the first source layer 31. The sacrificial layer 33 may be used to form a third source layer in a subsequent process. Subsequently, a second source layer 32 may be formed on the sacrificial layer 33. The second source layer 32 may include a polysilicon layer. The second source layer 32 may have a grain size different from that of the second part P2. In an embodiment, the second part P2 may have a smaller grain size than the second source layer 32.

Before the sacrificial layer 33 is formed, a first interface layer 34 may be formed on the first source layer 31. The first interface layer 34 may include a material having a high etch selectivity with respect to the sacrificial layer 33. Before the second source layer 32 is formed, a second interface layer 35 may be formed on the sacrificial layer 33. The second interface layer 35 may include a material having a high etch selectivity with respect to the sacrificial layer 33. The sacrificial layer 33 may include polysilicon, and the first interface layer 34 or the second interface layer 35 may include an oxide.

Referring to FIG. 4B, a stack ST may be formed on the second source layer 32. The stack ST may include first material layers 41 and second material layers 42 that are alternately stacked. The first material layers 41 may be used to form a word line, a bit line, a selection line, and the like, and the second material layers 42 may be used to form an insulating layer. The first material layers 41 may each include a material having a high etch selectivity with respect to the second material layers 42. For example, the first material layers 41 may each include a sacrificial material such as a nitride, and the second material layers 42 may each include an insulating material such as an oxide. In another example, the first material layers 41 may each include a conductive material such as polysilicon, tungsten, or molybdenum, and the second material layers 42 may each include an insulating material such as an oxide.

Subsequently, a channel structure CH passing through the stack ST may be formed. The channel structure CH may extend to the first source layer 31 through the second source layer 32, the second interface layer 35, the sacrificial layer 33, and the first interface layer 34. In an embodiment, after an opening passing through the stack ST and exposing the first source layer 31 is formed, a memory layer 44, a channel layer 43, and an insulating core 45 may be formed in the opening. For reference, an electrode structure may be formed instead of the channel structure CH.

Subsequently, a first opening OP1 passing through the stack ST may be formed. The first opening OP1 may pass through the second source layer 32 and expose the second interface layer 35 or the sacrificial layer 33. When the first opening OP1 is formed, a first etching gas including fluorine (F) may be used. In an embodiment, a C₄F₈ gas may be used as the first etching gas. After the etching process, fluorine may remain on the surface of the second interface layer 35 or the sacrificial layer 33.

Referring to FIG. 4C, a first passivation layer 46 may be formed. The first passivation layer 46 may be formed on a sidewall of the second source layer 32. In an embodiment, the first passivation layer 46 may be formed by selectively oxidizing the second source layer 32. The first passivation layer 46 may be used to protect the second source layer 32 in a subsequent process. The first passivation layer 46 may include an oxide.

Subsequently, a spacer 47 may be formed in the first opening OP1. The spacer 47 may be formed along a sidewall of the stack ST. The spacer 47 may extend along the surface of the first passivation layer 46. In an embodiment, a spacer layer may be formed along an inner surface of the first opening OP1 and then an entire surface of the spacer layer may be etched to form the spacer 47. The spacer 47 may be used to protect the stack ST in a subsequent process. The spacer 47 may be a single layer or a multilayer layer. The spacer 47 may include an oxide or a nitride, or a combination thereof. In an embodiment, the spacer 47 may include a first nitride layer, a second nitride layer, and an oxide layer between the first nitride layer and the second nitride layer.

At least a part of the spacer 47 may be formed in a high-temperature process. In an embodiment, the nitride layer included in the spacer 47 may be deposited in a high temperature process of 700° C. or higher. As the high-temperature process is performed, a first component of the first etching gas remaining on the surface of the sacrificial layer 33 may be diffused into the first source layer 31. In an embodiment, fluorine (F) may be diffused into the second part P2 of the first source layer 31 through the sacrificial layer 33 and the first interface layer 34.

The first component introduced into the first source layer 31 may be diffused along a grain boundary. Accordingly, when the grain size of the first source layer 31 is large, the first component may be diffused into the first source layer 31 along the grain boundary. Since the grain boundary is dense when the grain size of the first source layer 31 is small, it is difficult for the first component to be diffused into the first source layer 31.

Since the second part P2 is located closer to the surface than the first part P1, the first component is introduced into the second part P2 of the first source layer 31. The first component may migrate along the grain boundary of the second part P2, but stays in the second part P2 due to the dense grain structure. In an embodiment, the second part P2 serves as a diffusion barrier, and may prevent or minimize diffusion of the first component into the first part P1.

Referring to FIG. 4D, the sacrificial layer 33 may be removed through the first opening OP1 to form a second opening OP2. The sacrificial layer 33 may be selectively etched to form the second opening OP2. The second opening OP2 may expose the channel structure CH, and may expose the memory layer 44. The second opening OP2 may expose the first interface layer 34 or the second interface layer 35. For reference, the first interface layer 34 or the second interface layer 35 might not be formed, and in such a case, the second part P2 or the second source layer 32 may be exposed through the second opening OP2.

Subsequently, the memory layer 44 may be removed through the second opening OP2. A portion of the memory layer 44 exposed through the second opening OP2 may be etched. Accordingly, the channel layer 43 may be exposed into the second opening OP2. When the memory layer 44 is etched, the first interface layer 34 or the second interface layer 35 may be etched. Accordingly, the second part P2 or the second source layer 32 may be exposed into the second opening OP2.

When the memory layer 44 is etched, a second etching gas including hydrogen may be used. In such a case, a compound may be generated by reaction between the first component of the first etching gas included in the second part P2 and a second component of the second etching gas. In an embodiment, a HF gas and an NH₃ gas may be used as the second etching gas, and fluorine (F) and hydrogen (H) may react to generate HF.

Due to the dense grain structure of the second part P2, the compound HF may stay in the second part P2 without diffusing into the first part P1. The compound may be located at the grain boundary of the second part P2, and may damage the grain boundary while moving along the grain boundary. According to an embodiment of the present disclosure, the second part P2 has a dense grain boundary structure, and thus may prevent or minimize diffusion of the compound HF into the first part P1. Accordingly, even though the first source layer 31 is damaged by the compound HF, the damaged area may be minimized. As the second part P2 may be used as a chemical diffusion barrier, the first part P1 may maintain a rigid structure.

Referring to FIG. 4E, a third source layer 36 may be formed in the second opening OP2. In an embodiment, a conductive layer may be formed in the first opening OP1 and the second opening OP2. Subsequently, the conductive layer may be etched to etch a portion formed in the first opening OP1, so that the third source layer 36 may be formed. When the conductive layer is etched, the spacer 47 may protect the stack ST. After the conductive layer is etched, the spacer 47 may be removed. When the spacer 47 is removed, the first passivation layer 46 may be removed together or may remain. The third source layer may include polysilicon, metal, or the like.

Subsequently, a second passivation layer 48 may be formed by oxidizing the second part P2. In an embodiment, the second passivation layer 48 may be formed by oxidizing a portion of the second part P2 exposed through the first opening OP1. When the first source layer 31 does not include the second part P2, the first source layer 31 may be damaged by the compound HF migrating inside along the grain boundary, and some regions thereof may be relatively less oxidized due to cracks or the like in the surface. Accordingly, the surface of the first source layer 31 may be non-uniformly oxidized, and the second passivation layer 48 having a sufficient thickness might not be formed. On the contrary, in an embodiment, when the first source layer 31 includes the second part P2, the migration of the compound HF to the first part P1 along the grain boundary may be prevented or minimized. Accordingly, the surface of the first source layer 31 may be uniformly oxidized, and the second part P2 may be oxidized to form the second passivation layer 48 having a sufficient thickness. During the oxidation process, the compound HF remaining in the second part P2 may be removed.

When the second part P2 is oxidized, the sidewall of the third source layer 36 may be oxidized. In such a case, the second passivation layer 48 may extend along the sidewall of the third source layer 36. The second part P2 may or might not partially remain between the second passivation layer 48 and the first part P1.

Referring to FIG. 4F, the first material layers 41 may be selectively removed through the first opening OP1 to form third openings OP3. For example, the first material layers 41 may be selectively etched using a wet etching process using phosphoric acid.

When the first material layers 41 are etched, the first source layer 31 may be damaged. When the first source layer 31 is damaged due to the compound HF in the previous process, the second passivation layer 48 having a sufficient thickness might not be formed, so that the first source layer 31 might not be protected by the second passivation layer 48. Accordingly, in the process of selectively etching the first material layers 41, the previously damaged first source layer 31 may be additionally damaged and some regions thereof may be lost. According to an embodiment of the present disclosure, the first part P1 may substantially maintain a rigid grain structure due to the dense grain boundary structure of the second part P2. Accordingly, in an embodiment, damage to the first source layer 31 may be prevented or minimized in the process of etching the first material layers 41.

Referring to FIG. 4G, third material layers 51 may be formed in the third openings OP3. Accordingly, the first material layers 41 may be replaced with the third material layers 51. The third material layers 51 may each include a conductive material, and each include metal such as tungsten or molybdenum. A gate structure GST including the third material layers 51 and the second material layers 42 that are alternately stacked may be formed. For reference, when the first material layers 41 each include a conductive material and the second material layers 42 each include an insulating material, the first material layers 41 may be silicided without forming the third openings OP3.

Subsequently, the first opening OP1 to the source contact structure SCT may be formed. The source contact structure SCT may include a contact plug 53 and an insulating spacer 54. First, the insulating spacer 54 may be formed on an inner wall of the first opening OP1. After the spacer layer is formed along the inner surface of the first opening OP1, an entire surface of the spacer layer may be etched to form the insulating spacer 54. When the spacer layer is etched, the second passivation layer 48 may be etched, and the first source layer 31 may be exposed. Subsequently, the contact plug 53 may be formed in the first opening OP1. The contact plug 53 may be electrically connected to the first source layer 31. The contact plug 53 may come into contact with the first part P1.

According to the manufacturing method described above, the first source layer 51 having a different grain structure may be formed depending on the region. In an embodiment, through the second part P2 having a dense grain structure, damage to the first source layer S1 may be prevented or minimized during the manufacturing process.

Although embodiments according to the technical idea of the present disclosure have been described above with reference to the accompanying drawings, this is only for explaining the embodiments according to the concept of the present disclosure, and the present disclosure is not limited to the above embodiments. Various types of substitutions, modifications, and changes for the embodiments may be made by those skilled in the art, to which the present disclosure pertains, without departing from the technical idea of the present disclosure defined in the following claims, and it should be construed that these substitutions, modifications, and changes belong to the scope of the present disclosure.

What is claimed is:

1. A semiconductor device comprising:
a first source layer including a first part having a first grain size and a second part having a second grain size smaller than the first grain size;
a gate structure on the first source layer; and
a channel structure extending to the first part of the first source layer through the gate structure and the second part of the first source layer.

2. The semiconductor device of claim 1, further comprising:
a second source layer located between the first source layer and the gate structure.

3. The semiconductor device of claim 2, wherein the second part is located between the first part and the second source layer.

4. The semiconductor device of claim 2, wherein the second part has a smaller grain size than the second source layer.

5. The semiconductor device of claim 2, further comprising:
a third source layer located between the first source layer and the second source layer.

6. The semiconductor device of claim 5, wherein the second part has a smaller grain size than the third source layer.

7. The semiconductor device of claim 5, wherein the second part extends along an interface between the first source layer and the third source layer.

8. The semiconductor device of claim 1, further comprising:
a source contact structure passing through the gate structure and electrically connected to the first source layer.

9. The semiconductor device of claim 8, wherein the source contact structure comprises:
a contact plug electrically connected to the first source layer; and
an insulating spacer surrounding a sidewall of the contact plug.

10. The semiconductor device of claim 9, wherein the contact plug and the second part are separated by the insulating spacer.

11. A semiconductor device comprising:
a first source layer including a first part and a second part, wherein the second part has a denser grain structure than the first part;
a gate structure on the first source layer;
a second source layer located between the first source layer and the gate structure; and
a source contact structure extending to the first source layer through the gate structure and the second source layer,
wherein the second part extends along an interface between the first source layer and the second source layer.

12. The semiconductor device of claim 11, further comprising:
a channel structure passing through the gate structure, the second source layer, and the second part.

13. The semiconductor device of claim 11, wherein the second part has a grain size smaller than the first part.

14. The semiconductor device of claim 11, wherein the second part has a grain boundary density larger than the first part.

15. A manufacturing method of a semiconductor device, the manufacturing method comprising:
forming a first part of a first source layer, the first part having a first grain size;
forming a second part of the first source layer on the first part, the second part having a second grain size smaller than the first grain size;
forming a stack on the first source layer; and
forming a channel structure passing through the stack and the second part.

16. The manufacturing method of claim 15, wherein the forming of the second part comprises:
forming a silicon seed on a surface of the first part;
supplying at least one of a nitrogen gas and a carbon gas to the surface of the first part; and
forming the second part by crystallizing silicon from the silicon seed.

17. The manufacturing method of claim 15, wherein the first part and the second part are formed in-situ.

18. The manufacturing method of claim 15, further comprising:
forming a sacrificial layer on the first source layer;
forming a first opening passing through the stack and exposing the sacrificial layer;
forming a second opening exposing the second part by removing the sacrificial layer through the first opening; and
forming a second source layer in the second opening.

19. The manufacturing method of claim 18, further comprising:
forming a spacer on an inner wall of the first opening.

20. The manufacturing method of claim 19, wherein the forming of the spacer is performed in a high-temperature process, and a first component of a first etching gas used to form the first opening is diffused into the second part by the high-temperature process.

21. The manufacturing method of claim 20, wherein diffusion of the first component into the first part is substantially prevented by the second part.

22. The manufacturing method of claim 18, wherein the channel structure includes a channel layer and a memory layer surrounding the channel layer, and
the manufacturing method further comprises:
etching the memory layer to expose the channel layer through the second opening.

23. The manufacturing method of claim 22, wherein a compound is generated by reaction between a first component of a first etching gas used to form the first opening and a second component of a second etching gas used to etch the memory layer, and the second part includes the compound.

24. The manufacturing method of claim 18, further comprising:
forming a passivation layer by oxidizing the second part exposed through the first opening.

25. The manufacturing method of claim 18, further comprising:
forming a source contact structure in the first opening, the source contact structure being electrically connected to the first source layer.

26. A manufacturing method of a semiconductor device, the manufacturing method comprising:
forming a first part of a source layer;
forming a second part of the source layer on the first part, the second part having a denser grain structure than the first part;
forming a stack including first material layers and second material layers that are alternately stacked, on the source layer;
forming an opening passing through the stack and exposing the second part; and
forming a passivation layer by partially oxidizing the second part through the opening.

27. The manufacturing method of claim 26, wherein the forming of the second part comprises:
forming a silicon seed on a surface of the first part;
supplying at least one of a nitrogen gas and a carbon gas to the surface of the first part; and
crystallizing silicon from the silicon seed.

28. The manufacturing method of claim 26, further comprising:
replacing the first material layers with third material layers through the opening.

29. The manufacturing method of claim 28, wherein, in the replacing of the first material layers with the third material layers, the source layer is protected by the passivation layer.

30. The manufacturing method of claim 26, further comprising:
forming a source contact structure in the opening, the source contact structure passing through the passivation layer and electrically connected to the source layer.
